(19) United States
(12) Patent Application Publication
(10) Pub. No.: US 2017/0263716 A1
(43) Pub. Date: Sep. 14, 2017

(54) SEMICONDUCTOR DEVICE

(71) Applicant: KABUSHIKI KAISHA TOSHIBA, Tokyo (JP)

(72) Inventors: Yasunobu SAITO, Nomi Ishikawa (JP); Toshiyuki NAKA, Nonoichi Ishikawa (JP)

(21) Appl. No.: 15/243,451

(22) Filed: Aug. 22, 2016

(30) Foreign Application Priority Data
Mar. 8, 2016 (JP) 2016-044873

(51) Int. Cl. H01L 29/40; H01L 29/66; H01L 29/778; H01L 29/20; H01L 29/205

(52) U.S. Cl. CPC H01L 29/404; H01L 29/2003; H01L 29/205; H01L 29/7787; H01L 29/66462; H01L 29/401

(57) ABSTRACT

A semiconductor device includes a first nitride semiconductor layer, a second nitride semiconductor layer on the first nitride semiconductor layer, a source electrode on the second nitride semiconductor layer and spaced from the source electrode, a drain electrode on the second nitride semiconductor layer and spaced from the source electrode, a gate electrode between the drain and source electrodes, an interlayer insulating film on the second nitride semiconductor layer, a first field plate electrode in contact with an upper surface of the second nitride semiconductor layer at a location between the gate and drain electrodes, and a second field plate electrode extending through the interlayer insulating film and connected to the first field plate electrode. An end of the second field plate electrode on the source electrode side is closer to the drain electrode than is an end of the first field plate electrode on the source electrode side.

### CROSS-REFERENCE TO RELATED APPLICATION

This application is based upon and claims the benefit of priority from Japanese Patent Application No. 2016-044873, filed Mar. 8, 2016, the entire contents of which are incorporated herein by reference.

### FIELD

An embodiment described herein relates generally to a semiconductor device.

### BACKGROUND

In a nitride semiconductor device having a horizontal orientation, electric field concentration between a gate electrode and a drain electrode in some cases causes electrons of the two-dimensional electron gas to be trapped, and the trapped electrons generate a current collapse phenomenon. A field plate electrode is known as means for alleviating this electric field concentration.

There is a type of a field plate electrode that extends through an interlayer insulating film and is connected to a nitride semiconductor layer. If such a field plate electrode extends on the interlayer insulating film toward the gate electrode, trapped electrons accumulate on a boundary surface between an extending portion thereof and the interlayer insulating film. As a result, the current collapse phenomenon preventing effect might not be sufficiently achieved.

### DESCRIPTION OF THE DRAWINGS

FIG. 1 is a sectional view illustrating a schematic configuration of a semiconductor device according to the embodiment.

FIG. 2 is an enlarged view of the field plate electrodes of FIG. 1.

FIG. 3 is a sectional view illustrating a nitride semiconductor layer forming process.

FIG. 4 is a sectional view illustrating an electrode forming process.

FIG. 5 is a sectional view illustrating a gate insulation film forming process.

FIG. 6 is a sectional view illustrating a gate electrode forming process.

FIG. 7 is a sectional view illustrating an interlayer insulating film forming process.

FIG. 8 is a sectional view illustrating a contact hole forming process.

### DETAILED DESCRIPTION

In general, according to an embodiment, a semiconductor device includes a first nitride semiconductor layer, a second nitride semiconductor layer on the first nitride semiconductor layer and having a larger band gap than the first nitride semiconductor layer, a source electrode on the second nitride semiconductor layer, a drain electrode on the second nitride semiconductor layer and spaced from the source electrode in a first direction, a gate electrode between the drain electrode and the source electrode, an interlayer insulating film on the second nitride semiconductor layer, a first field plate electrode in contact with an upper surface of the second nitride semiconductor layer at a location between the gate electrode and the drain electrode, and a second field plate electrode extending through the interlayer insulating film and connected to the first field plate electrode. An end portion of the second field plate electrode on the source electrode side thereof is closer to the drain electrode than is an end portion of the first field plate electrode on the source electrode side thereof.

Hereinafter, an embodiment according to the exemplary embodiment will be described with reference to the drawings. The embodiment does not limit the invention.

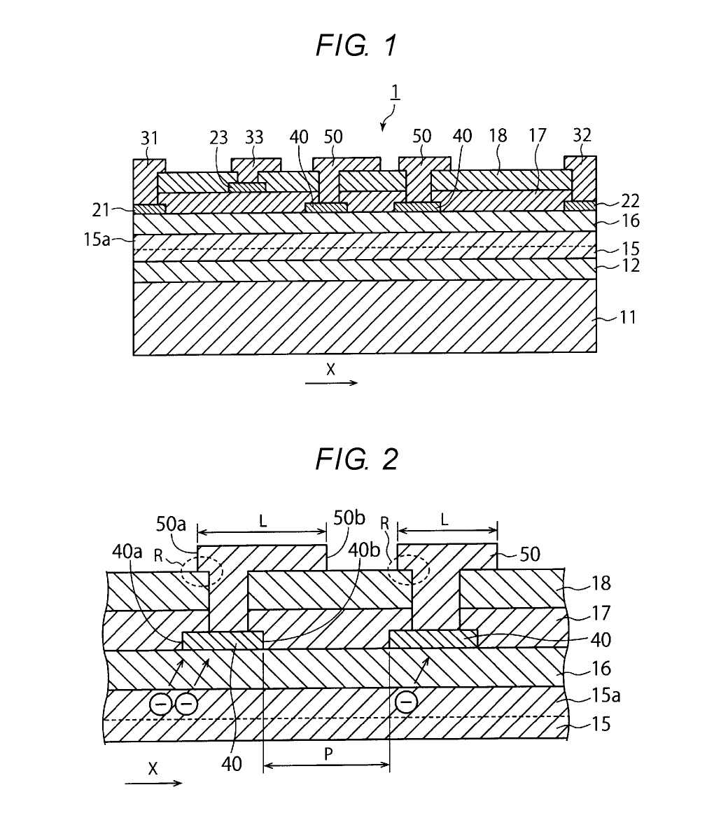

FIG. 1 is a sectional view illustrating a schematic configuration of a semiconductor device according to the embodiment. As illustrated in FIG. 1, a semiconductor device 1 according to the embodiment is provided with a substrate 11, a buffer layer 12, nitride semiconductor layers 15 and 16, a gate insulation film 17, an interlayer insulating film 18, a source electrode 21, a drain electrode 22, a gate electrode 23, and field plate electrodes 40 and 50.

Among components of the semiconductor device 1 described above, the nitride semiconductor layer 15 corresponds to a first nitride semiconductor layer, and the nitride semiconductor layer 16 corresponds to a second nitride semiconductor layer. The field plate electrode 40 corresponds to a first field plate electrode, and the field plate electrode 50 corresponds to a second field plate electrode.

The substrate 11 is made of silicon, silicon carbide (SiC), or the like. On the substrate 11, the buffer layer 12 is provided. On the buffer layer 12, the nitride semiconductor layer 15 is provided.

The nitride semiconductor layer 15 is, for example, a layer of undoped gallium nitride represented by a composition formula of AlₓGa₁₋ₓN (0≦x<1). The nitride semiconductor layer 16 is provided on the nitride semiconductor layer 15. The band gap of the nitride semiconductor layer 16 is wider than the band gap of the nitride semiconductor layer 15. The nitride semiconductor layer 16 is, for example, an undoped or an n-type nitride semiconductor layer represented by a composition formula of Al_{y}Ga_{1-y}N (y>x).

A two-dimensional electron gas 15a is generated at and adjacent to a boundary surface between the nitride semiconductor layer 15 and the nitride semiconductor layer 16. The two-dimensional electron gas 15a forms an electrical current path between the drain electrode 22 and the source electrode 21. An electrical current that flows in this electrical current path is controlled by adjusting a voltage of the gate electrode 23. Accordingly, the semiconductor device 1 is turned on or off.

An undoped layer means a layer formed without impurities being intentionally introduced. A layer in which impurities are diffused from an upper layer and a lower layer and mixed with the layer by heat treating conducted after the layer is formed and/or in a manufacturing process of the layer is not an undoped layer. The undoped layer has an impurity concentration that is even lower than 1×10¹⁶/cm³.

The gate insulation film 17 is provided on the nitride semiconductor layer 16. On the gate insulation film 17, the interlayer insulating film 18 is provided. The gate insulation film 17 may not be provided. In this case, the interlayer insulating film 18 is provided on the nitride semiconductor layer 16. In the specification, “the interlayer insulating film 18 provided on the nitride semiconductor layer 16” includes a case where the interlayer insulating film 18 is indirectly provided on the nitride semiconductor layer 16 with the gate insulation film 17 placed therebetween, and a case where the interlayer insulating film 18 is directly provided on the nitride semiconductor layer 16. The gate insulation film 17 and the interlayer insulating film 18 are made of, for example, silicon oxide (SiO₂) or the like.

The source electrode 21 is provided on the nitride semiconductor layer 16. Wiring 31 is connected to the source electrode 21. The drain electrode 22 is spaced away from the source electrode 21 in a first direction X (refer to an arrow in FIG. 1) on the nitride semiconductor layer 16. Wiring 32 is connected to the drain electrode 22. The gate electrode 23 is provided on the gate insulation film 17, between the source electrode 21 and the drain electrode 22. Wiring 33 is connected to the gate electrode 23. A metal insulator semiconductor (MIS) gate structure, a Schottky gate structure, and a junction gate structure can be applied to the gate electrode 23.

The field plate electrode 40 is an electrode that is in ohmic contact with an upper surface of the nitride semiconductor layer 16, between the gate electrode 23 and the drain electrode 22. TiAl based alloy that includes titanium and aluminum, for example, is used to form the field plate electrode 40. In this embodiment, the field plate electrode 40 is covered with the gate insulation film 17.

The field plate electrode 50 extends through the interlayer insulating film 18 and is connected to the field plate electrode 40. Gold, aluminum, and other types of metals, for example, are used to form the field plate electrode 50.

Hereinafter, the field plate electrodes 40 and 50 according to this embodiment will be described in detail with reference to FIG. 2. FIG. 2 is an enlarged view of the field plate electrodes 40 and 50.

As illustrated in FIG. 2, a plurality of the field plate electrodes 40 are spaced from each other in the first direction X. A field plate electrode 40 that is at a position closer to the drain electrode 22 has a larger electric potential. It is preferable to provide a large number of the field plate electrodes 40 in order to reduce an electric field concentration that is generated between the drain electrode 22 and the gate electrode 23. In this case, however, the size of the semiconductor device 1 might become larger. Therefore, in this embodiment, the closer to the drain electrode 22, the smaller is the interval P between the field plate electrodes 40 in the first direction X in order to provide a large number of the field plate electrodes 40 at the drain electrode 22 side where an effect of reducing the electric field concentration is greater.

A plurality of the field plate electrodes 50 are connected to the plurality of the field plate electrodes 40, respectively. Each of the field plate electrodes 50 has an end portion 50a at a source electrode side and an end portion 50b at a drain electrode side. The end portion 50a on the source electrode side of the second field plate 50 is located in the first direction X closer to the drain electrode 22 than is an end portion 40a of the field plate electrode 40 at the source electrode side thereof, in order to prevent electrons from being accumulated in a boundary surface region R (refer to FIG. 2) between the field plate electrode 50 and the interlayer insulating film 18.

The end portion 50b on the drain electrode side of the second field plate 50 extends closer in the first direction X to the drain electrode 22 than does the end portion 40b of the field plate electrode 40 on the drain electrode side thereof such that a difference in electric potential between the field plate electrode 40 and the field plate electrode 50 further reduces the electric field concentration. The closer to the drain electrode 22, the smaller is the width L of each of the field plate electrodes 50 in the first direction X in order to provide a large number of the field plate electrodes 40 at the drain electrode 22 side of the device.

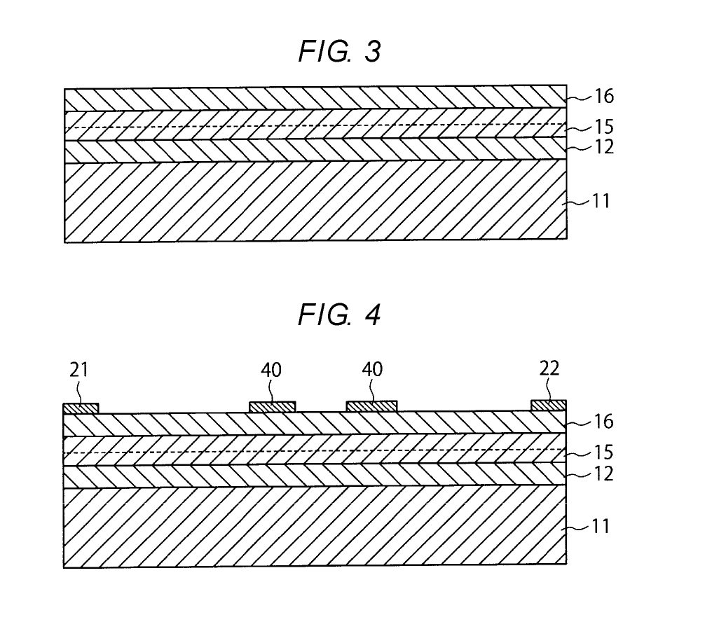

Following the description on the semiconductor device 1 according to the embodiment described above, hereinafter, a manufacturing process of the semiconductor device 1 will be described with reference to FIG. 3 to FIG. 8.

FIG. 3 is a sectional view illustrating a nitride semiconductor layer forming process. In the process in FIG. 3, on the substrate 11, the buffer layer 12 and the nitride semiconductor layers 15 and 16 are sequentially formed, for example, by an epitaxial growth.

FIG. 4 is a sectional view illustrating an electrode forming process. After the nitride semiconductor layers 15 and 16 are formed, the source electrode 21, the drain electrode 22, and the field plate electrode 40 are formed on an upper surface of the nitride semiconductor layer 16 as illustrated in FIG. 4.

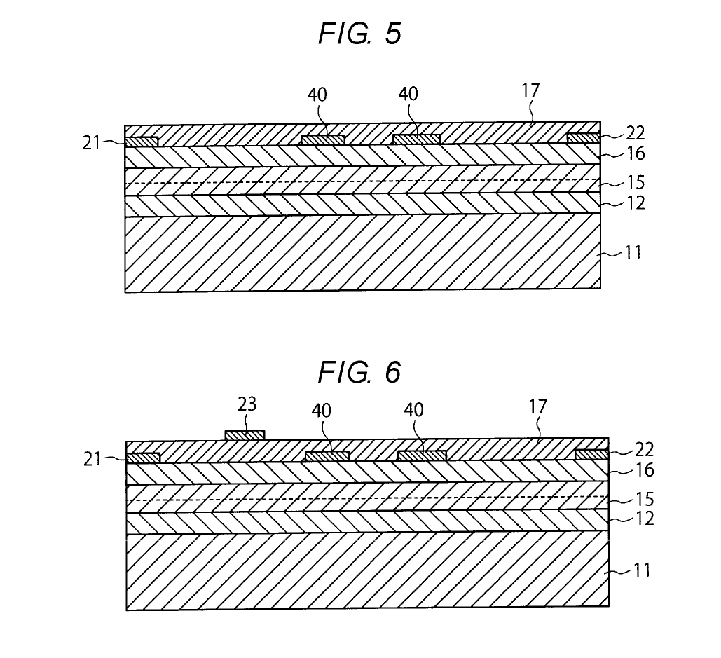

FIG. 5 is a sectional view illustrating a gate insulation film 17 forming process. After the source electrode 21, the drain electrode 22, and the field plate electrode 40 are formed, the gate insulation film 17 is formed on the nitride semiconductor layer 16 so as to cover the source electrode 21, the drain electrode 22, and the field plate electrodes 40 as illustrated in FIG. 5.

FIG. 6 is a sectional view illustrating a gate electrode 23 forming process. After the gate insulation film 17 is formed, the gate electrode 23 is formed on the gate insulation film 17 as illustrated in FIG. 6.

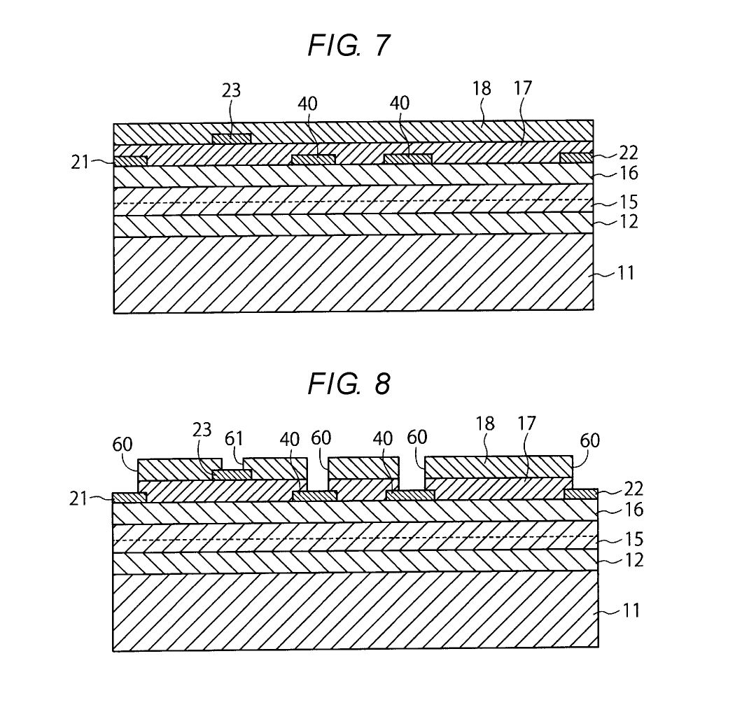

FIG. 7 is a sectional view illustrating an interlayer insulating film 18 forming process. After the gate electrode 23 is formed, the interlayer insulating film 18 is formed on the gate insulation film 17 so as to cover the gate electrode 23 as illustrated in FIG. 7.

FIG. 8 is a sectional view illustrating a contact hole forming process. After the interlayer insulating film 18 is formed, a contact hole 60 is formed as illustrated in FIG. 8. The contact hole 60 extends through the gate insulation film 17 and the interlayer insulating film 18, exposing the source electrode 21, the drain electrode 22, the gate electrode 23, and the field plate electrode 40. Thereafter, with the contact hole 60 being filled with metal, the wirings 31 to 33 and the field plate electrodes 50 are formed as illustrated in FIG. 1.

According to the embodiment described hereinbefore, the end portion 50a of the field plate electrode 50 extends further toward the source electrode than the side of the contact hole 60. As a result, between the extended end portion 50a and the interlayer insulating film 18, a boundary surface region R (refer to FIG. 2) exists, in which electrons are likely to accumulate. Accordingly, on the one hand, the electric field concentration reducing effect caused by the end portion 50b of the field plate electrode 50 allows a current collapse phenomenon preventing effect to be achieved, but on the other hand, the electric field concentration reducing effect results in a creation of a region in which electrons are likely to be trapped by the end portion 50a. Accordingly, this region might become a factor in causing another current collapse phenomenon.

In the embodiment, however, the end portion 50a is disposed on the drain electrode side of the second field plate electrode 50, but the end portion 50a is closer to the drain electrode 22 than is the end portion 40a of the field plate electrode 40. For this reason, electric lines of force that face the boundary surface region R are blocked by the field plate electrode 40, such that electrons of the two-dimensional electron gas 15a are prevented from being directed toward the boundary surface region R. Accordingly, since the end portion 50b achieves the electric field concentration reducing effect while the end portion 50a of the field plate electrode 50 is prevented from becoming a factor in causing another current collapse phenomenon, the current collapse phenomenon preventing effect can be enhanced.

In this embodiment, a plurality of the field plate electrodes 40 are in contact with the upper surface of the nitride semiconductor layer 16, and the electric potentials of the plurality of the field plate electrodes 40 correspond to each of a plurality of electric potentials between the gate electrode 23 and the drain electrode 22. Accordingly, the number of interlayer insulating films can be reduced since the plurality of field plate electrodes do not need to be formed into a stair or stepped configuration using multiple insulating layers. As a result, it is possible to reduce trapping of electrons which is likely to occur on the boundary surface of the interlayer insulating film.

While an embodiment has been described, the embodiment has been presented by way of example only, and is not intended to limit the scope of the invention. Indeed, the novel embodiment described herein may be embodied in a variety of other forms; furthermore, various omissions, substitutions and changes in the form of the embodiment described herein may be made without departing from the spirit of the invention. The accompanying claims and their equivalents are intended to cover such forms or modifications as would fall within the scope and spirit of the invention.

What is claimed is:

1. A semiconductor device comprising:
a first nitride semiconductor layer;
a second nitride semiconductor layer on the first nitride semiconductor layer and having a larger band gap than the first nitride semiconductor layer;
a source electrode on the second nitride semiconductor layer;
a drain electrode on the second nitride semiconductor layer and spaced from the source electrode in a first direction;
a gate electrode between the drain electrode and the source electrode;
an interlayer insulating film on the second nitride semiconductor layer;
a first field plate electrode in contact with an upper surface of the second nitride semiconductor layer at a location between the gate electrode and the drain electrode; and
a second field plate electrode extending through the interlayer insulating film and connected to the first field plate electrode,
wherein an end of the second field plate electrode on the source electrode side thereof is closer to the drain electrode than is an end of the first field plate electrode on the source electrode side thereof.

2. The device according to claim 1, wherein the end of the second field plate electrode on the drain electrode side thereof is located closer to the drain electrode than is the end of the first field plate electrode on the drain electrode side thereof.

3. The device according to claim 1, wherein
a plurality of the first field plate electrodes are spaced from each other in the first direction, and
a plurality of the second field plate electrodes are connected to the plurality of first field plate electrodes, respectively.

4. The device according to claim 3, wherein the interval between the first field plate electrodes in the first direction becomes smaller with decreasing distance to the drain electrode.

5. The device according to claim 3, wherein the width of each of the plurality of second field plate electrodes in the first direction becomes smaller with decreasing distance to the drain electrode.

6. The device according to claim 1, wherein the first field plate electrode is in ohmic contact with the upper surface of the second nitride semiconductor layer.

7. The device according to claim 6, wherein the first field plate electrode comprises titanium and aluminum.

8. A semiconductor device comprising:
a first nitride semiconductor layer having a composition represented by the formula AlₓGa₁₋ₓN (0≦x<1);
a second nitride semiconductor layer on the first nitride semiconductor layer and having a composition represented by the formula Al_{y}Ga_{1-y}N (y>x);
a source electrode on the second nitride semiconductor layer;
a drain electrode on the second nitride semiconductor layer and spaced from the source electrode in a first direction;
a gate electrode between the drain electrode and the source electrode;
an interlayer insulating film on the second nitride semiconductor layer;
a first field plate electrode in contact with an upper surface of the second nitride semiconductor layer in a location between the gate electrode and the drain electrode; and
a second field plate electrode extending through the interlayer insulating film and connected to the first field plate electrode,
wherein an end of the second field plate electrode on the source electrode side thereof is closer to the drain electrode than is the end of the first field plate electrode on the source electrode side thereof.

9. The device according to claim 8, wherein the end of the second field plate electrode on the drain electrode side thereof is located closer to the drain electrode than the end of the first field plate electrode at the drain electrode side thereof.

10. The device according to claim 8, wherein
a plurality of the first field plate electrodes are spaced from each other in the first direction, and
a plurality of the second field plate electrodes are connected to the plurality of first field plate electrodes, respectively.

11. The device according to claim 10, wherein the spacing between the first field plate electrodes becomes smaller with decreasing distance to the drain electrode.

12. The device according to claim 10, wherein the width of each of the plurality of second field plate electrodes in the first direction becomes smaller with decreasing distance to the drain electrode.

13. The device according to claim 8, wherein the first field plate electrode is in ohmic contact with the upper surface of the second nitride semiconductor layer.

14. The device according to claim 13, wherein the first field plate electrode comprises titanium and aluminum.
